(19) United States
(12) Patent Application Publication
(10) Pub. No.: US 2012/0161269 A1
(43) Pub. Date: Jun. 28, 2012

(54) LOW-CROSSTALK FRONT-SIDE ILLUMINATED IMAGE SENSOR

(75) Inventors: Christophe Aumont, Le Touvet (FR); Jean-Pierre Oddou, Champagnier (FR); Jérôme Vaillant, Grenoble (FR); Patrick Gros D'Aillon, Biviers (FR)

(73) Assignees: STMicroelectronics S.A., Montrouge (FR); Commissariat a l`Energie Atomique et aux Energies Alternatives, Paris (FR); STMicroelectronics (Crolles 2) SAS, Crolles (FR)

(21) Appl. No.: 13/334,392

(22) Filed: Dec. 22, 2011

(30) Foreign Application Priority Data
Dec. 23, 2010 (FR) 10/61139

(51) Int. Cl. H01L 31/0232; H01L 31/18

(52) U.S. Cl. 257/432; 438/70; 257/E31.127

(57) ABSTRACT

A front-side illuminated image sensor, including photodetection regions, charge transfer elements, and an interconnection stack, all formed at the surface of a semiconductor substrate, microcavities being formed in the interconnection stack in front of the photodetection regions, microcavities being filled with materials forming color filters including metal pigments, regions of a material forming a barrier against ionic diffusion extending on the lateral walls of the microcavities.

### CROSS REFERENCE TO RELATED APPLICATIONS

This application claims the priority benefit of French patent application number 10/61139, filed on Dec. 23, 2010, entitled LOW-CROSSTALK FRONT-SIDE ILLUMINATED IMAGE SENSOR, which is hereby incorporated by reference to the maximum extent allowable by law.

### BACKGROUND OF THE INVENTION

1. Technical Field

Embodiments relate to front-side illuminated image sensors. More specifically, the embodiments relate to such image sensors with a low crosstalk, as well as to a method for manufacturing such image sensors.

2. Discussion of the Related Art

A front-side illuminated image sensor is generally formed of a semiconductor substrate having photodetection regions and charge transfer components formed on its first surface. A stack of interconnection levels is then formed on the first surface of the substrate. Each interconnection level comprises conductive tracks and vias separated by an insulating material, this enabling to interconnect the different components of the image sensor.

In operation, the device is illuminated through the first surface of the substrate. To provide a good detection, the conductive elements of the interconnection stack are offset from the photodetection areas. This enables limiting the number of obstacles to incident light beams and thus to attenuate parasitic phenomena of reflection of the incident photons.

Many front-side illuminated image sensor structures have been provided to improve the detection of sensors, especially to avoid the reflection of incident photons between the point of penetration of the photons into the device and the photogenerated charge collection area. However, such structures all have their limits.

### SUMMARY

An embodiment provides a front-side illuminated image sensor providing a high-quality detection.

An embodiment provides a method for manufacturing such an image sensor.

Thus, an embodiment provides a front-side illuminated image sensor, comprising photodetection regions, charge transfer elements, and an interconnection stack, all formed at the surface of a semiconductor substrate, microcavities being formed in the interconnection stack in front of the photodetection regions, said microcavities being filled with materials forming color filters comprising metal pigments, regions of a material forming a barrier against ionic diffusion extending only on the lateral walls of said microcavities.

According to an embodiment, the interconnection levels comprise conductive tracks and vias separated by an insulating material, the material forming a barrier against ionic diffusion having a refractive index greater than the refractive index of said insulating material.

According to an embodiment, the materials forming color filters have refractive indexes greater than the refractive index of the insulating material of the interconnection levels.

According to an embodiment, the material forming a barrier against ionic diffusion is selected from the group comprising silicon nitride, silicon carbonitride, and titanium nitride, or is formed of a stack of tantalum nitride and tantalum.

According to an embodiment, the material forming a barrier against ionic diffusion has a thickness ranging between 30 and 60 nm.

According to an embodiment, upper interconnection levels of the interconnection stack are removed above the charge transfer elements, the upper interconnection levels being kept at the periphery of the image sensor.

According to an embodiment, the upper interconnection levels ensure the forming of pads of connection to the outside of the sensor.

An embodiment further provides a method for manufacturing a front-side illuminated image sensor, comprising the steps of: forming, at the surface of a semiconductor substrate, photodetection regions and charge transfer elements; forming levels of an interconnection stack over the entire structure, said levels comprising conductive tracks and vias separated by an insulating material; removing upper interconnection levels in front of the photodetection regions and of the charge transfer elements to form an opening in this location; forming microcavities in at least some of the remaining interconnection levels in front of the photodetection regions; forming a conformal barrier layer against ionic diffusion over the entire device; anisotropically etching the barrier layer, whereby the lateral walls of the microcavities are covered with portions of the barrier layer; and filling the microcavities with materials forming color filters.

According to an embodiment, the method further comprises the steps of: filling the opening with a transparent material; and forming microlenses capable of focusing light rays towards the photodetection regions on the transparent material.

According to an embodiment, the barrier layer against ionic diffusion has a refractive index greater than that of the insulating material of the interconnection levels and of the materials forming color filters, the insulating material having a refractive index smaller than that of the materials forming color filters.

The foregoing and other objects, features, and advantages will be discussed in detail in the following non-limiting description of specific embodiments in connection with the accompanying drawings.

### BRIEF DESCRIPTION OF THE DRAWINGS

FIG. 1 illustrates a front-side illuminated image sensor; and

FIGS. 2A to 2G illustrate results of steps of a method for forming a front-side illuminated image sensor according to an embodiment, FIG. 2G illustrating a finished image sensor according to an embodiment.

For clarity, the same elements have been designated with the same reference numerals in the different drawings and, further, as usual in the representation of integrated image sensors, the various drawings are not to scale.

### DETAILED DESCRIPTION

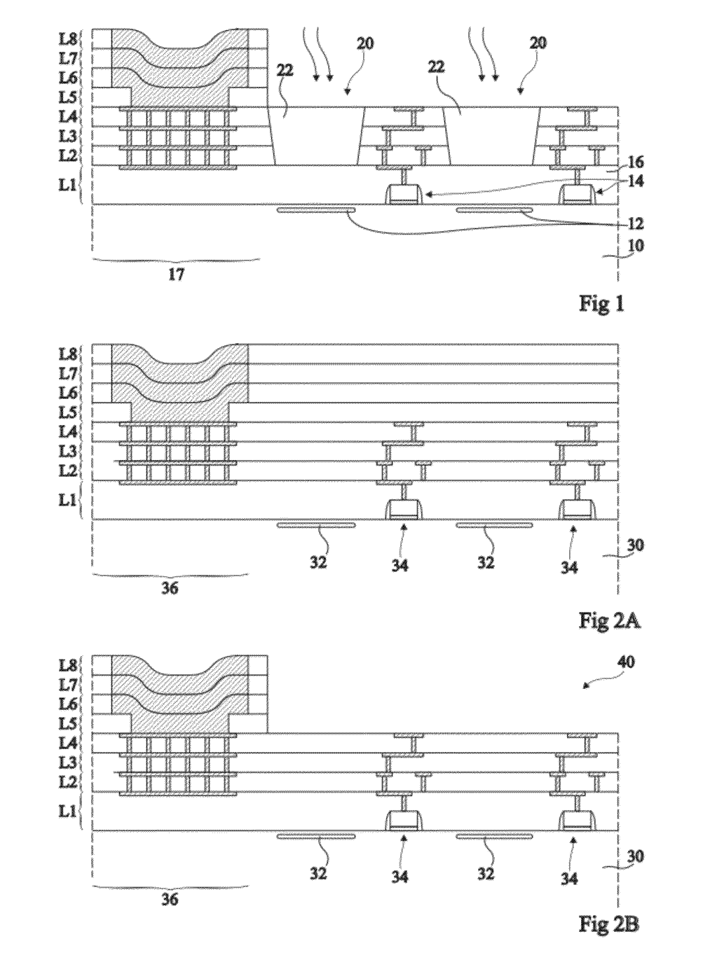

FIG. 1 illustrates a structure that improves the operation of a front-side illuminated image sensor. The structure of FIG. 1 is an intermediary structure on which a planarization step and a microlens forming step for example remain to be carried out to obtain a finished product.

At the surface of a semiconductor substrate 10 are defined pixels, each comprising a region for collecting photogenerated charges 12, or photodiode, formed at the surface of the substrate and one or several components for transferring the photogenerated charges 14, in the form of MOS transistors in the shown example. An insulating layer 16 is formed at the surface of substrate 10 and conductive elements (tracks and vias) are formed in this insulating layer to obtain electric connections on the different charge capture and transfer elements. A region 17, generally peripheral, of substrate 10 (left-hand portion of FIG. 1) comprises no pixel and is provided to form pads of contact with the outside of the circuit.

Insulating layer 16 and the conductive regions which are formed therein define a first interconnection level L1 of the sensor. Other interconnection levels, L2 to L8, are formed above first level L1 in front of the pixels and of the peripheral area of contact pads. Each interconnection level comprises conductive tracks and vias (hatched regions) separated by an insulating material. An etching has been carried out to remove the upper interconnection levels, L5 to L8 in FIG. 1, in front of the pixels. In the shown example, only the four first interconnection levels are kept in front of the pixels. Indeed, generally, only four interconnection levels are necessary to connect the different pixel elements together, which is not the case in peripheral area 17 where all the interconnection levels are used. This structure of area 17 enables, in known fashion, to form connection pads distant from the photodetection areas to avoid damaging them on installation of the image sensor in its final environment.

Two areas are provided in front of each of the image sensor pixels: a first area for collecting photogenerated charges (12), forming the most part of the surface of a pixel, and a second area comprising the elements for transferring the photogenerated charges (14). In front of the first area, part at least of the remaining interconnection levels (in the shown example, levels L2 to L4) is removed to form, in front of each of the photodiodes, microcavities 20.

The presence of microcavities 20 in front of the photodiodes enables, on the one hand, to decrease the thickness of the material located above the photodiode, which improves the efficiency of a microlens formed afterwards in front of the photodiodes, and on the other hand to avoid that incident rays are reflected by the various interfaces between materials present in the interconnection levels. This improves the detection of each of the pixels.

It has been provided to form structures with microcavities in which the interconnection levels formed above the pixels are covered with a thick transparent layer penetrating into the microcavities, after which color filters and microlenses are formed on the transparent layer.

In the example of FIG. 1, color filters 22 are directly formed in microcavities 20. This improves the detection of a color predefined by each of the pixels. Indeed, the forming of color filters as close as possible to the photodetection area enables to avoid for photons having the wavelength of a normally-filtered color to bypass the color filter and to be unduly captured by the charge collection area.

However, the present inventors have noted that the forming of color filters directly in the microcavities, rather than improving the pixel detection quality, adversely affects it.

To determine the cause of this degradation, the present inventors have studied the interactions between the different materials forming the device of FIG. 1. They have thus determined that such a degradation is due to the fact that the materials forming color filters are formed of a transparent material in which color metal pigments are inserted. Such metal pigments are ionic particles which tend to migrate into the insulating material of the surrounding interconnection levels, which adversely affects the image sensor detection.

To improve the detection, the present inventors provide forming a barrier layer against the diffusion of ionic particles towards the surrounding insulating material on the microcavity walls.

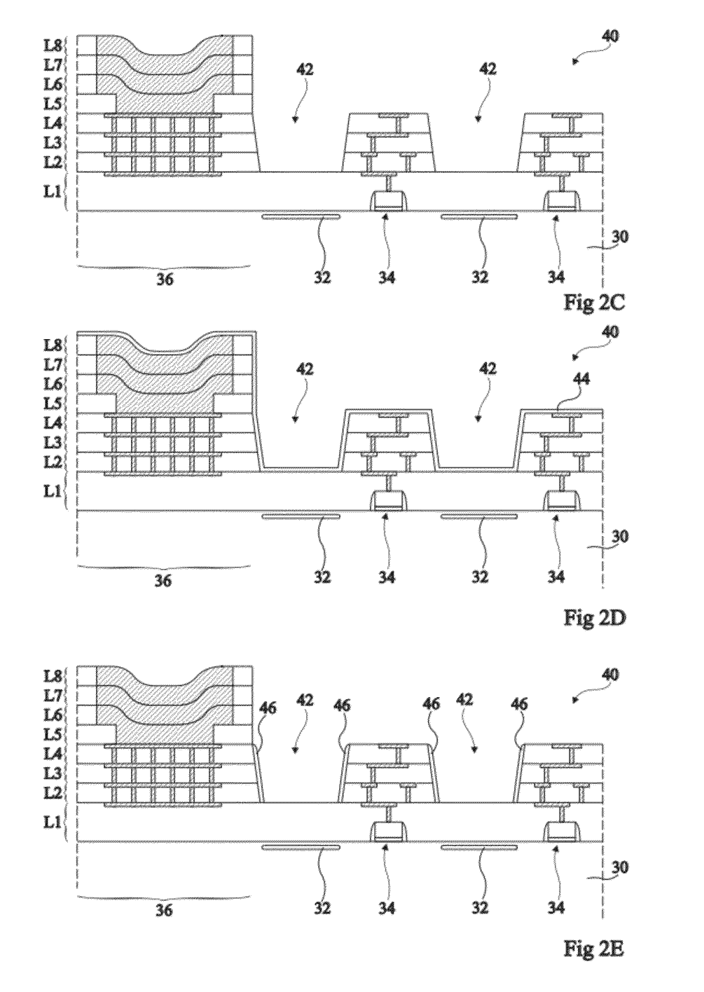

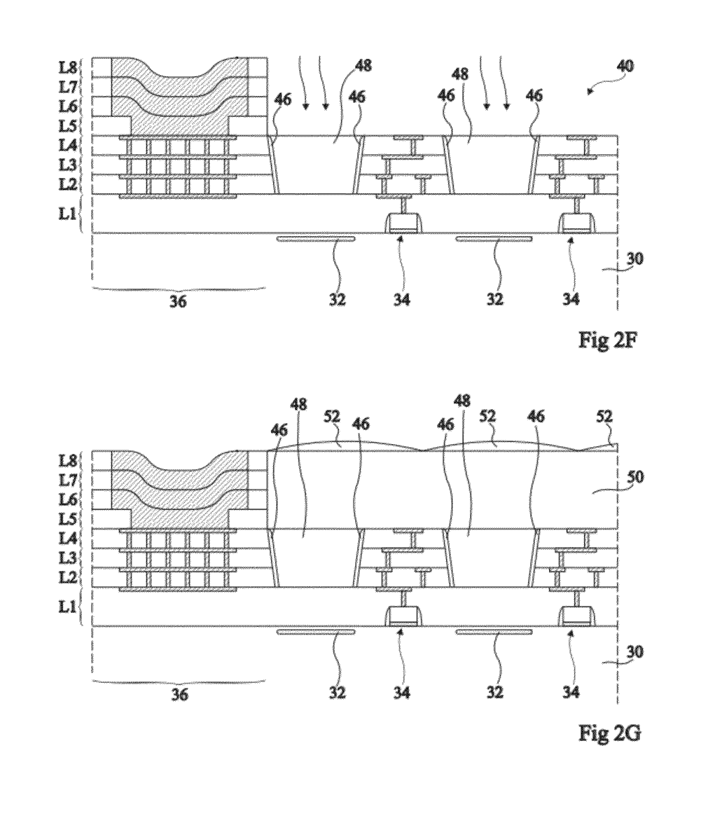

FIGS. 2A to 2G illustrate results of steps of a method for forming such a front-side illuminated image sensor. FIG. 2G illustrates a finished image sensor such as provided hereabove.

At the step illustrated in FIG. 2A, it is started from a structure comprising a substrate 30 having photogenerated charge collection regions 32 defined at its surface. Elements 34 for transferring the photogenerated charges, in the form of MOS transistors in the shown example, are provided at the surface of substrate 30. Each assembly formed of a photodetection element and of a charge transfer element defines a pixel. Conventionally, many pixels, in the form of an array, may be defined at the center of the image sensor while the peripheral area thereof, 36 in FIGS. 2A to 2G, is provided to form pads of contact of the image sensor with its final environment.

Interconnection levels L1 to L8 are formed above substrate 30. Each interconnection level comprises conductive tracks and vias (shown with hatchings) separated by an insulating material. It should be noted that the number of interconnection levels is arbitrary in the drawings and may be different from eight.

Above the pixels, only the first interconnection levels are used and comprise conductive tracks used to form the electric connections necessary for the device to operate properly. In the shown example, four interconnection levels L1 to L4 are arbitrarily used for these connections.

In area 36 of the image sensor reserved to the forming of pads of contact to the outside of the device, all interconnection levels L1 to L8 are used to form conductive contact pads on the front surface side of the device.

At the step illustrated in FIG. 2B, an opening 40 has been formed on the front surface side of the device to remove, above the pixels, the last interconnection levels which are not used to interconnect elements of the image sensor pixels. In the shown example, opening 40 eliminates interconnection levels L5 to L8 in front of the pixels. As an example, opening 40 may be obtained by forming of an adapted mask at the surface of the device of FIG. 2A and by etching of the insulating material of the interconnection levels through this mask.

At the step illustrated in FIG. 2C, microcavities 42 have been formed from the front surface of the device in interconnection levels L4, L3, and L2, above photogenerated charge collection areas 32. Microcavities 42 may be formed by any conventional process, especially by etching through a predefined mask.

In the shown example, microcavities 42 extend all the way to the interface between first and second interconnection levels L1 and L2. It should be noted that it may also be provided to form microcavities 42 all the way to substrate 30 if desired.

At the step illustrated in FIG. 2D, the front surface of the device has been covered with a conformal layer 44 made of a material forming a barrier against ionic diffusion. Layer 44 follows the contour of the front surface of the device and thus covers the lateral walls and the bottom of microcavities 42. This layer may be formed by any known conformal deposition method.

Preferably, layer 44 is a relatively thin layer, for example, with a thickness ranging between 30 and 60 nm, to have the smallest possible influence on the detection.

At the step illustrated in FIG. 2E, an anisotropic etching of layer 44 has been performed to remove the portions of this layer formed at the bottom of microcavities 42, at the surface of the contact pads and at the surface of interconnection stack L1 to L4. A structure in which only the walls of microcavities 42 are covered with portions 46 of layer 44 is thus obtained. The steps of forming portions 46 only on the walls of microcavities 42 limits the loss of signal at the bottom of microcavities 42. Thus, the elimination of the portions of layer 44, which are formed at the bottom of microcavities, decreases the absorption and the reflexion of signals at the bottom of the microcavities.

The presence of portions 46 of the material forming a barrier against ionic diffusion enables to block the leakage of metal pigments from the regions forming color filters to the neighboring insulating material. Among materials capable of forming a barrier against ionic diffusion, silicon nitride, silicon carbonitride, and titanium nitride may be mentioned. Layer 44 may also be formed of a stack of several layers forming a barrier by their association, for example, a stack of a tantalum nitride layer and of a tantalum layer.

At the step illustrated in FIG. 2F, microcavities 42 have been filled with materials 48 playing the role of color filters. As an example, such color filters may be formed in several steps, one step per filter color being provided.

The barrier-forming materials of portions 46 are materials having a high refractive index, greater than the refractive index of the insulating material used in the adjacent interconnection levels, so that portion 46 guide light towards the photogenerated charge collection areas. Further, in order for light rays arriving with a strong incidence on portions 46 to be reflected towards photogenerated charge collection areas 32, it may also be provided for filter materials 48 to have refractive indexes greater than the refractive index of the insulating material used in the adjacent interconnection levels.

As an example, the material of the layer forming a barrier against ionic diffusion may be silicon nitride, with a refractive index close to 2. Then, if the color filter material has a refractive index close to 1.65, the insulating material used to insulate the conductive tracks and vias of the interconnection stack will be silicon oxide having a refractive index close to 1.5.

At the step illustrated in FIG. 2G, a transparent material 50 has been formed in opening 40 to obtain a planar device. Microlenses 52 are then formed above the transparent material layer to focus the incident light rays towards each charge collection area 32.

It should be noted that the transparent material layer is optional and that the microlenses may be formed directly on color filters 48 if a planar structure is not desired.

Then, due to the presence of layer 46, a device in which the metal pigments contained in the color filters no longer interfere with the adjacent insulating material is obtained. Further, due to the high refractive index of portions 46, these portions also guide the incident waves towards the associated charge collection area 32.

Specific embodiments of the present invention have been described. Various alterations and modifications will occur to those skilled in the art. In particular, it should be noted that regions 46 may be made of any other known material forming a barrier against ionic diffusion, preferably with a high refractive index.

Such alterations, modifications, and improvements are intended to be part of this disclosure, and are intended to be within the spirit and the scope of the present invention. Accordingly, the foregoing description is by way of example only and is not intended to be limiting. The present invention is limited only as defined in the following claims and the equivalents thereto.

What is claimed is:

1. A front-side illuminated image sensor, comprising photodetection regions, charge transfer elements, and an interconnection stack, all formed at the surface of a semiconductor substrate, microcavities being formed in the interconnection stack in front of the photodetection regions, said microcavities being filled with materials forming color filters comprising metal pigments, regions of a material forming a barrier against ionic diffusion extending only on the lateral walls of said microcavities.

2. The sensor of claim 1, wherein the interconnection levels comprise conductive tracks and vias separated by an insulating material, the material forming a barrier against ionic diffusion having a refractive index greater than the refractive index of said insulating material.

3. The sensor of claim 2, wherein the materials forming color filters have refractive indexes greater than the refractive index of the insulating material of the interconnection levels.

4. The sensor of claim 1, wherein the material forming a barrier against ionic diffusion is selected from the group comprising silicon nitride, silicon carbonitride, and titanium nitride, or is formed of a stack of tantalum nitride and tantalum.

5. The sensor of claim 1, wherein the material forming a barrier against ionic diffusion has a thickness ranging between 30 and 60 nm.

6. The sensor of claim 1, wherein upper interconnection levels of the interconnection stack are removed above the charge transfer elements, said upper interconnection levels being kept at the periphery of the image sensor.

7. The sensor of claim 6, wherein the upper interconnection levels ensure the forming of pads of connection to the outside of the sensor.

8. A method for manufacturing a front-side illuminated image sensor, comprising the steps of:
forming, at the surface of a semiconductor substrate, photodetection regions and charge transfer elements;
forming levels of an interconnection stack over the entire structure, said levels comprising conductive tracks and vias separated by an insulating material;
removing upper interconnection levels in front of the photodetection regions and of the charge transfer elements to form an opening in this location;
forming microcavities in at least some of the remaining interconnection levels in front of the photodetection regions;
forming a conformal barrier layer against ionic diffusion over the entire device;
anisotropically etching said barrier layer, whereby the lateral walls of the microcavities are covered with portions of the barrier layer; and
filling the microcavities with materials forming color filters.

9. The method of claim 8, further comprising the steps of:
filling the opening with a transparent material; and
forming microlenses capable of focusing light rays towards the photodetection regions on the transparent material.

10. The method of claim 8, wherein the barrier layer against ionic diffusion has a refractive index greater than that of the insulating material of the interconnection levels and of the materials forming color filters, said insulating material having a refractive index smaller than that of the materials forming color filters.
